(19) United States
(12) Patent Application Publication
(10) Pub. No.: US 2011/0043204 A1
(43) Pub. Date: Feb. 24, 2011

(54) MAGNETIC RESONANCE SYSTEM AND METHOD FOR COMPUTERIZED RULE-BASED CONTROL THEREOF

(76) Inventors: Wolfgang Bielmeier, Nuernberg (DE); Gerhard Brinker, Erlangen (DE); Swen Campagna, Engelthal (DE); Thorsten Feiweier, Poxdorf (DE); Bernd Kuehn, Uttenreuth (DE); Mathias Nittka, Baiersdorf (DE); Carsten Prinz, Erlangen (DE); Thorsten Speckner, Nuernberg (DE)

Correspondence Address: SCHIFF HARDIN, LLP;PATENT DEPARTMENT, 233 S. Wacker Drive-Suite 6600, CHICAGO, IL, 60606-6473, US

(21) Appl. No.: 12/859,461

(22) Filed: Aug. 19, 2010

(30) Foreign Application Priority Data
Aug. 19, 2009 (DE) 10 2009 038 139.2

(51) Int. Cl. G01R 33/44

(52) U.S. Cl. 324/307

(57) ABSTRACT

In a magnetic resonance system according to a measurement protocol defined in advance and comprising multiple acquisition parameters, wherein given a non-compliance with at least one limit value (which is automatically established before the beginning of a subject-specific measurement data acquisition)—in particular a SAR limit value and/or a magneto-stimulation limit value and/or a hardware limit value—by the measurement protocol, an adaptation of at least one acquisition parameter ensues using at least one (in particular user-defined) protocol-specific rule for compliance with the limit value, and the measurement data acquisition ensues automatically according to the adapted acquisition parameters.

### BACKGROUND OF THE INVENTION

1. Field of the Invention

The invention concerns a method to control a magnetic resonance system according to a measurement protocol defined in advance and having multiple acquisition parameters.

2. Description of the Prior Art

In the field of magnetic resonance it is typical to define one-time measurement protocols for specific measurements, such as for specific diagnostic questions and/or body regions to be examined, that can then be used for a number of such measurement data acquisitions. Such a protocol consequently contains a number of acquisition parameters that determine the acquisition workflow and serve to control the magnetic resonance system.

However, at the same time it can be important in magnetic resonance to comply with specific limit values relative to the patient or the hardware. The radiation exposure of the patient—defined by the specific absorption rate (SAR)—may not be too high, and magneto-stimulation (for example due to gradients that are switched too quickly) may not occur. Moreover, the hardware of the magnetic resonance system can also have limits (for example with regard to the current feed) that must be adhered to.

Since a measurement protocol is defined in advance for a number of measurements, in the case of a specific individual measurement data acquisition it can occur, for example, due to properties of a subject (in particular the weight of a patient) and/or a selected slice orientation that one or more such limit values are exceeded and the measurement cannot be implemented at all, or cannot be implemented safely for the patient.

It was accordingly proposed to originally limit the selection of the acquisition parameters for a protocol so that measurement values cannot be exceeded, even given disadvantageous assumptions for the specific measurement data acquisition. However, in all other cases the assumption of a “worst-case scenario” entails a degraded image quality, or extended measurement time in comparison to the optimal possible acquisition parameters.

Variants are also known in which the acquisition parameters of the measurement protocol can be freely selected, but upon at least one limit value being exceeded, the measurement data acquisition cannot be started and the user must manually adapt the measurement protocol. In another variant the system can also submit suggestions—for example in the form of pop-ups—to the user that are oriented toward the worst-case scenario described above.

That means that either a poorer image quality or, respectively, a longer acquisition time must be accepted, or an interaction with the user is necessary that occasionally entails a time-consuming manual adaptation of acquisition parameters.

### SUMMARY OF THE INVENTION

An object of the invention is to provide a control method that simplifies the adaptation of a measurement protocol, in particular with transparency for a user, and that enables improved acquisition or image qualities in spite of the automation.

This object is achieved in accordance with the invention in a method of the aforementioned type wherein, upon non-compliance with at least one limit value (which is automatically established before the beginning of a subject-specific measurement data acquisition) such as an SAR limit value and/or a magneto-stimulation limit value and/or a hardware limit value, by the measurement protocol, an adaptation of at least one acquisition parameter ensues automatically using at least one (in particular user-defined) protocol-specific rule for compliance with the limit value, and the measurement data acquisition ensues automatically according to the adapted acquisition parameters.

In the method according to the invention, the acquisition parameters thus always can be selected so that the limit values are complied with without having to thereby resort to a worst-case scenario. Rather, it is possible to automatically select an ultimately optimized adjustment of the acquisition parameters of the measurement protocol through the use of an optimization method depending on the design of the rules, and then to automatically conduct the measurement data acquisition without additional user interaction. Acquisition parameters of the measurement protocol can consequently be modified automatically, optimized to the point complying with the limitations. User interactions are thus minimized. An interaction-free start of the sequence is thus possible.

Transparency thus is provided since the at least one rule is known to the user, and in particular is also defined by the user. For example, at least one rule can be simply defined as well upon generation of the measurement protocol. Strategies thus can be predetermined in order to automatically modify the acquisition parameters to the resolution of patient and/or hardware limitations at the sequence start. Upon generating a measurement protocol, the user thus indicates not only which acquisition parameters should normally be adopted but also a strategy—determined by rules—as to how a specific measurement data acquisition should proceed upon exceeding limit values. Naturally such rules, particularly if they are user-defined, can also be varied and adapted after the fact, as this naturally applies for the entire measurement protocol.

In a further embodiment of the method according to the invention the automatic adaptation of specific adaptation values are normally associated with the acquisition parameters of the measurement protocol. At least a portion of the acquisition parameters is provided with attributes that can specify whether and in what manner an adaptation of the acquisition parameters should be allowed. For example, the fundamental adaptability of the acquisition parameters and/or a tolerance range and/or an optimization target—in particular the minimization of the acquisition parameter and/or a maximization of the acquisition parameter and/or a target value of the acquisition parameter—at least one priority of the adaptation can be used as an adaptation value. Naturally, other adaptation values are also conceivable, for example possible step intervals in the adaptation or the like. Naturally, additional rules can be provided, for example global rules that describe the general course of the optimization process based on the rules and allow a modification thereof.

For example, to achieve such an association of adaptation values to acquisition parameters of the measurement protocol, operator action properties, for each adjustment parameter, can be called up in which the corresponding adaptation values can be set (for example in a separate window in one embodiment), for example by a check mark if the acquisition parameter should be adaptable at all, a field to input a target value, or a minimization/maximization, input fields to select the tolerance ranges and the like. The definition of the rules thus can be comfortably integrated into the generation or processing of the measurement protocol.

According to the invention, the manner of adaptation based on the rules, thus ultimately the optimization, can be provided in different ways. In the case of multiple adaptable acquisition parameters, an adaptation order is associated with each of these, in particular through a priority wherein the acquisition parameters are accordingly sequentially adapted corresponding to the order. A list that is executed sequentially in order to obtain optimized acquisition parameters satisfying the limit values accordingly exists. Moreover, it can thereby also be provided that individual acquisition parameters occur repeatedly in order. For example, this can be reasonable when the tolerance range of an acquisition parameter was fully exploited without achieving a compliance with the limit value, but after achieving compliance with the limit value in a further step the order of the parameters can by all means be adjusted again with regard to a target value so that the limit values continue to be maintained.

It is also conceivable for the adaptation of the acquisition parameters to ensue within the scope of an optimization procedure, wherein a cost function is optimized by repeated variation of multiple acquisition parameters. Such optimization methods are widely known and, for example, can directly contain the compliance with the limit values as boundary conditions.

If, at the sequence start, a conflict with a patient limitation or hardware limitation was established in the form of the limit value, the acquisition parameters are thus adapted with the method according to the invention, corresponding to the modification strategy determined by the rules, until the conflict is resolved; the limit value is thus complied with. However, cases are also conceivable in which these rules are not sufficient to ensure compliance with the limit values. An embodiment of the method provides that a message is output to a user if a limit value cannot be complied with through adaptation using the rules. The user is then made aware that the automatic adaptation of the parameters of the measurement protocol was not possible, and thus initially a measurement data acquisition cannot take place. An adaptation of the acquisition parameters to comply with the limit value can be then conducted by a user. A limitation of the selectable values of the acquisition parameters can ensue in order for a safe compliance with the limit value, meaning that in this case a limitation of the acquisition parameter selection which is defined by a worst-case scenario can ensue. However, in general it is also possible for adaptations that go beyond the rules to also be evaluated by the magnetic resonance system and offered to the user (for example as pop-ups). Many options are conceivable for this case.

A magnetic resonance system in accordance with the invention has a control device that is fashioned to implement the method according to the invention. User interactions are additionally minimized given such a magnetic resonance system, and the measurement data acquisition can begin completely automatically using adapted but nevertheless optimized acquisition parameters of the measurement protocol, even given established overrun of a limit value at the sequence start.

### BRIEF DESCRIPTION OF THE DRAWINGS

FIG. 1 is a flowchart for control of a magnetic resonance system using the method according to the invention.

FIG. 2 schematically illustrates a magnetic resonance system constructed and operating in accordance with the invention.

### DESCRIPTION OF THE PREFERRED EMBODIMENTS

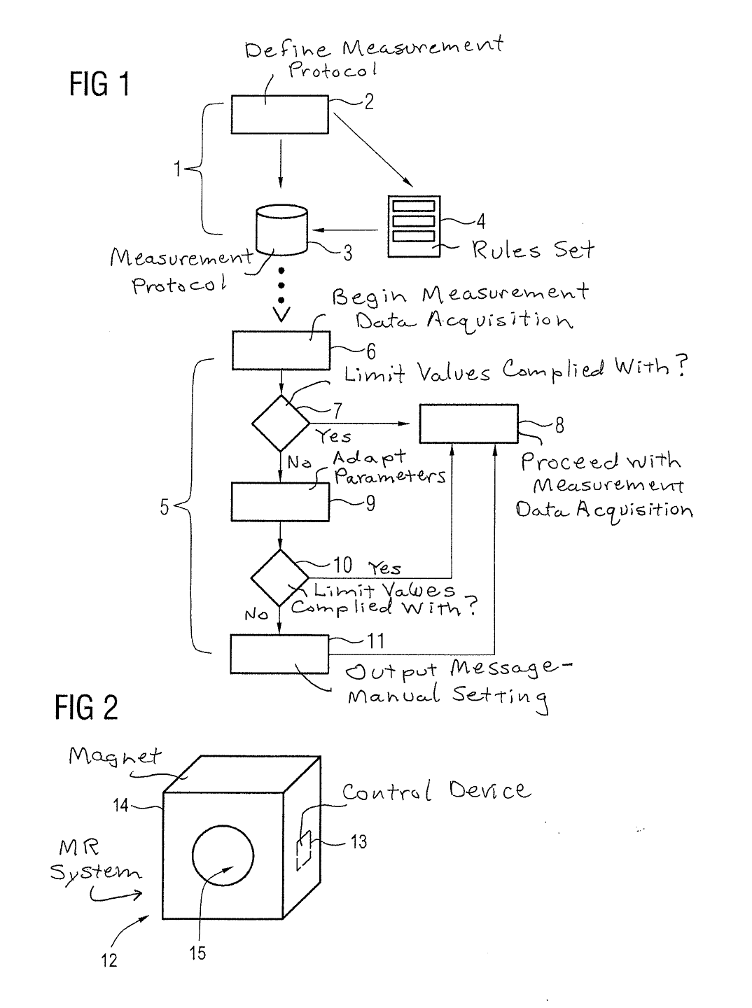

FIG. 1 shows the control of a magnetic resonance system using the method according to the invention. In a chronologically preset method part 1, in Step 2 a measurement protocol 3 is initially defined—triggered by a specific measurement data acquisition—that establishes acquisition parameters for a specific class (type) of measurement data acquisition. However, a modification strategy is also defined by a set 4 of rules in addition to this establishment of ac parameters in the measurement protocol 3.

Additional attributes in the form of adaptation values, such as the basic adaptation capability of an acquisition parameter, a tolerance range, an optimization target and at least one priority of the adaptation, can be associated an acquisition parameter. An optimization target can be defined in various ways. For example, a designation can be made that an acquisition parameter should be minimized or maximized, or the achievement of a target value can be specified as an optimization target. Naturally, additional, in particular global, rules are also possible. A subsequent processing of the measurement protocol 3, and thus also of the set 4 of rules, can naturally also take place.

As an example, a possible modification strategy is presently described as a reaction of radio-frequency-dependent conflicts (SAR, magneto-stimulation) in a T1-TSE-based measurement protocol. Here adaptable acquisition parameters of the measurement protocol should be the flip angle of the refocusing pulse, the number of concatenations and the repetition time. In the measurement protocol it is initially specified for the acquisition parameters that the flip angle should be 180°, the number of concatenations should be 1 and the repetition time should be set to 400 ms. Adaptation values are now additionally associated with these acquisition parameters. As a tolerance for the flip angle it is thus specified that it can be reduced to 110°; 180° is specified as a target value and 1 and 3 are specified as a priority (explained in further detail with regard to the second method part). The number of concatenations can be increased to 2, however it should be minimal. The priority is 2. Given a repetition time with priority 4, the target value is 400 ms, wherein an increase to up to 450 ms as a tolerance range should however be possible. The consequences of these rules defined by adaptation values are now explained with regard to the second method part 5, which should initially be described in general again and pertains to a concrete measurement data acquisition of a specific subject. In Step 6 a user has specified that the measurement data acquisition should begin with the measurement protocol 3. All information specific to this measurement data acquisition is thus present, such that in Step 7 it can be checked whether diverse limit values—related to a patient or the hardware, for example—can be complied with. In the present example discussed above, the compliance with a SAR limit value is checked. If this is complied with, the measurement data acquisition ensues in Step 8. However, if these limit values are exceeded an adaptation of the adaptable acquisition parameters of the measurement protocol 3 occurs in Step 9 using the set 4 of rules, wherein optimized acquisition parameters complying with the limit values should be determined.

This is explained again in detail in the example shown above. The priorities cited there—1 and 3 for the flip angles, 2 for the number of concatenations and 4 for the repetition time—define an order in which the adaptation of the acquisition parameters should ensue. The flip angle of the refocusing pulse is consequently initially reduced step by step in order to check whether the limit values are complied with the new value. If this is not the case, the number of concatenations is increased to 2. If this successfully resolves the conflict—consequently the compliance with the limit values is taken care of—at the third point the flip angle of the refocusing pulse (which is cited repeatedly) can possibly be increased again, wherein nevertheless the limit values are still complied with, in particular even the target value of 180°. However, if the second step—the increase of the number of concatenations—does not lead to the resolving of the conflict, the third step is de facto ineffective and an adaptation of the repetition time is considered as a fourth step.

In general, in the method according to the invention it is also possible to use arbitrarily complicated optimization methods that, for example, operate with an optimization of a cost function with simultaneous variation of multiple or all variable acquisition parameters. Such optimization methods are widely known and do not need to be presented here.

If it is established in Step 10 that an adaptation of the acquisition parameters of the measurement protocol was also successfully possible due to the predefined set of rules—thus all limit values are now complied with—the magnetic resonance system is correspondingly controlled, meaning that the measurement data acquisition ensues in Step 8 without an additional user interaction having been necessary after the selection of the sequence start in Step 6.

If a compliance with the limit values using the set 4 of rules turns out not to be possible, a corresponding message is output to a user, and the user must manually adapt the acquisition parameter selection, possibly with limitation of the acquisition parameter selection with regard to a worst-case scenario, so that the limit values are satisfied. Only then can a measurement data acquisition ensue in Step 8. These measures ensue in Step 11.

FIG. 2 shows a magnetic resonance (MR) system 12 with a computerized control device 13 that is fashioned (programmable) to execute the method according to the invention. Otherwise, the general design of the magnet 14 with the patient receptacle 15 and the remaining components of the magnetic resonance system 12 are widely known and need not be explained in detail here.

Although modifications and changes may be suggested by those skilled in the art, it is the intention of the inventors to embody within the patent warranted hereon all changes and modifications as reasonably and properly come within the scope of their contribution to the art.

We claim as our invention:

1. A method for controlling a magnetic resonance system comprising the steps of:
entering a measurement protocol into a computerized control unit of a magnetic resonance system, said measurement protocol comprising multiple data acquisition parameters that, in combination, define operation of the magnetic resonance system according to the measurement protocol;
providing said control unit with at least one limit value for at least one of said parameters;
providing said control unit with at least one rule, that is specific for said measurement protocol, for compliance with said at least one limit value;
upon non-compliance of said at least one parameter with said at least one limit value, automatically adapting said at least one parameter in said control unit using said rule, to generate an adapted measurement protocol; and
acquiring diagnostic data from the patient by operating said magnetic resonance system according to said adapted measurement protocol.

2. A method as claimed in claim 1 comprising implementing said rule in said control unit to select an adapted value for said at least one parameter from among a plurality of adaptation values for said at least one parameter, associated with said rule.

3. A method as claimed in claim 2 wherein said rule comprises adaptation values selected from the group consisting of a basic adaptation capability of said at least one parameter, a tolerance range for said at least one parameter, and a hierarchical priority for adaptation of said at least one parameter.

4. A method as claimed in claim 2 wherein said rule causes said control unit to implement an optimization procedure for said at least one parameter to cause said at least one parameter to be set to an adaptation value selected from the group consisting of a minimization of said at least one acquisition parameter, a maximization of said at least one acquisition parameter, and a target value of said at least one acquisition parameter.

5. A method as claimed in claim 1 comprising providing said control unit with a plurality of rules respectively for the multiple acquisition parameters, and sequentially adapting more than one of said multiple acquisition parameters in said control unit dependent on the respective rules associated therewith.

6. A method as claimed in claim 1 wherein said rule causes said control unit to implement an optimization procedure for said at least one parameter that optimizes a cost function for said at least one parameter through simultaneous variation of a plurality of said multiple parameters.

7. A method as claimed in claim 1 comprising emitting a humanly perceptible message from said control unit when said at least one limit value for said at least one parameter cannot be complied with by adaptation using said rule.

8. A method as claimed in claim 6 comprising allowing manual adaptation, via said control unit, of said at least one parameter upon output of said message.

9. A method as claimed in claim 8 comprising automatically, in said control unit, limiting said manual adaptation of said at least one parameter to a selected value that ensures safe operation of said magnetic resonance system.

10. A method as claimed in claim 1 comprising manually defining said rule by a manual entry into said control unit.

11. A magnetic resonance system comprising:
a magnetic resonance data acquisition unit;
a computerized control unit provided with a measurement protocol comprising multiple data acquisition parameters that, in combination, define operation of the magnetic resonance data acquisition unit according to the measurement protocol;
said control unit also being provided with at least one limit value for at least one of said parameters;
said control unit also being provided with at least one rule, that is specific for said measurement protocol, for compliance with said at least one limit value;
said control unit being configured, upon non-compliance of said at least one parameter with said at least one limit value, to automatically adapt said at least one parameter in said control unit using said rule, to generate an adapted measurement protocol; and
said control unit being configured to operate said magnetic resonance system according to said adapted measurement protocol to acquire diagnostic data from a patient.
